(19) United States
(12) Patent Application Publication
(10) Pub. No.: US 2020/0251582 A1
(43) Pub. Date: Aug. 6, 2020

(54) HIGH ELECTRON MOBILITY TRANSISTOR (HEMT) FIN FIELD-EFFECT TRANSISTOR (FINFET)

(71) Applicant: QUALCOMM Incorporated, San Diego, CA (US)

(72) Inventors: Xia Li, San Diego, CA (US); Gengming Tao, San Diego, CA (US); Bin Yang, San Diego, CA (US)

(21) Appl. No.: 16/266,267

(22) Filed: Feb. 4, 2019

(51) Int. Cl. H01L 29/778; H01L 29/20; H01L 29/66; H01L 29/10; H01L 21/02; H01L 27/092; H01L 29/51; H01L 21/8238

(52) U.S. Cl. CPC H01L 29/7786; H01L 29/2003; H01L 29/66462; H01L 29/1037; H01L 21/02362; H01L 21/823828; H01L 27/0924; H01L 29/517; H01L 21/823807; H01L 21/823821; H01L 21/0254

(57) ABSTRACT

Certain aspects of the present disclosure generally relate to a high electron mobility transistor and techniques for fabricating the same. Certain aspects of the present disclosure are directed to a semiconductor device. The semiconductor device generally includes a substrate; a channel region having a fin disposed above the substrate; a first barrier layer disposed adjacent to a first side and a second side of the first fin, wherein the first side and the second side of the first fin are opposite sides, the first barrier layer forming a heterojunction with the fin; a first dielectric layer disposed adjacent to a first side and a second side of the first barrier layer, wherein the first side and the second side of the first barrier layer are opposite sides; and a first gate region disposed adjacent to the first dielectric layer.

### TECHNICAL FIELD

Certain aspects of the present disclosure generally relate to electronic components and, more particularly, to a high electron mobility transistor.

### BACKGROUND

A wireless device (e.g., a cellular phone or a smartphone) in a wireless communication system may include a radio frequency (RF) transceiver to transmit and receive data for two-way communication. A mobile RF transceiver may include a transmit section for data transmission and a receive section for data reception. For data transmission, the transmit section may modulate an RF carrier signal with data to obtain a modulated RF signal, amplify the modulated RF signal to obtain an amplified RF signal having the proper output power level, and transmit the amplified RF signal via an antenna to a base station. For data reception, the receive section may obtain a received RF signal via the antenna and may amplify and process the received RF signal to recover data sent by the base station.

The transmit section of the mobile RF transceiver may amplify and transmit a communication signal. The transmit section may include one or more circuits for amplifying and transmitting the communication signal. The amplifier circuits may include one or more amplifier stages that may have one or more driver stages and one or more power amplifier stages. Each of the amplifier stages includes one or more transistors configured in various ways to amplify the communication signal. The transistors configured to amplify the communication signal are generally selected to operate at high frequencies for supporting communication enhancements, such as carrier aggregation. These transistors may be implemented using compound semiconductor transistors, such as bipolar junction transistors (BJTs), heterojunction bipolar transistors (HBTs), high electron mobility transistors (HEMTs), pseudomorphic high electron mobility transistors (pHEMTs), and the like. Further design challenges for mobile RF transceivers include performance considerations for meeting future Fifth Generation (5G) transmission frequency specifications.

### SUMMARY

Certain aspects of the present disclosure generally relate to a semiconductor device employing a heterojunction (e.g., a high electron mobility transistor) and techniques for fabricating the same.

Certain aspects of the present disclosure are directed to a semiconductor device. The semiconductor device generally includes a substrate; a channel region having a fin disposed above the substrate; a first barrier layer disposed adjacent to a first side and a second side of the first fin, wherein the first side and the second side of the first fin are opposite sides, the first barrier layer forming a heterojunction with the fin; a first dielectric layer disposed adjacent to a first side and a second side of the first barrier layer, wherein the first side and the second side of the first barrier layer are opposite sides; and a first gate region disposed adjacent to the first dielectric layer.

Certain aspects of the present disclosure are directed to a semiconductor device. The semiconductor device generally includes a substrate; a channel region having a first fin disposed above the substrate; a first barrier layer; a second barrier layer; a first dielectric layer, wherein the first barrier layer is disposed between the first dielectric layer and the fin, the first barrier layer forming a first heterojunction with the fin; a second dielectric layer, wherein the second barrier layer is disposed between the second dielectric layer and the fin, the second barrier layer forming a second heterojunction with the fin; a first gate region, wherein the first dielectric layer is disposed between the first barrier layer and the first gate region; and a second gate region, wherein the second dielectric layer is disposed between the second barrier layer and the second gate region.

Certain aspects of the present disclosure are directed to a method for fabricating a semiconductor device. The method generally includes forming a channel region having a fin above a substrate; forming a first barrier layer, the first barrier layer forming a heterojunction with the fin; forming a first dielectric layer, wherein the first barrier layer is disposed between the first dielectric layer and the fin; and forming a first gate region, wherein the first dielectric layer is disposed between the first barrier layer and the first gate region.

### BRIEF DESCRIPTION OF THE DRAWINGS

So that the manner in which the above-recited features of the present disclosure can be understood in detail, a more particular description, briefly summarized above, may be by reference to aspects, some of which are illustrated in the appended drawings. It is to be noted, however, that the appended drawings illustrate only certain typical aspects of this disclosure and are therefore not to be considered limiting of its scope, for the description may admit to other equally effective aspects.

FIGS. 1A, 1B, and 1C illustrate example implementations of a three-dimensional (3D) fin field-effect transistor (finFET) triple gate high electron mobility transistor (HEMT) device, in accordance with certain aspects of the present disclosure.

FIGS. 2A, 2B, and 2C illustrate example implementations of a 3D finFET double gate HEMT device, in accordance with certain aspects of the present disclosure.

FIGS. 3A-3V illustrate example operations for fabricating a semiconductor device, in accordance with certain aspects of the present disclosure.

FIG. 4 is a flow diagram illustrating example operations for fabricating a semiconductor device, in accordance with certain aspects of the present disclosure.

### DETAILED DESCRIPTION

The word “exemplary” is used herein to mean “serving as an example, instance, or illustration.” Any aspect described herein as “exemplary” is not necessarily to be construed as preferred or advantageous over other aspects.

As used herein, the term “connected with” in the various tenses of the verb “connect” may mean that element A is directly connected to element B or that other elements may be connected between elements A and B (i.e., that element A is indirectly connected with element B). In the case of electrical components, the term “connected with” may also be used herein to mean that a wire, trace, or other electrically conductive material is used to electrically connect elements A and B (and any components electrically connected therebetween).

### Example Transistor

A high electron mobility transistor (HEMT) is a type of field-effect transistor (FET) that relies on a junction between different semiconductor materials with different bandgaps to form a heterojunction. High electron mobility transistors improve upon heterojunction transistors by supporting higher transmission frequencies, which may meet future Fifth Generation (5G) performance specifications. Electrons from an n-type region of a HEMT move through a crystal lattice and may remain close to the heterojunction, forming a two-dimensional (2D) hole gas (also referred to as an electron gas). The electrons are able to move freely as other donor electrons may not be present, eliminating (or at least reducing) electron collisions, increasing the mobility of the electrons in the hole gas. A bias voltage applied to a gate modulates the number of electrons in the 2D hole gas to control the conductivity of the HEMT device.

5G and millimeter wave (mmWave) use high frequency (e.g., higher than 6 GHz) power amplifiers (PAs) with low thermal effect. However, 2D gallium nitride (GaN) PAs may have high thermal effect and low power efficiency. Certain aspects of the present disclosure are directed to three-dimensional (3D) double and triple gate fin field-effect transistor (finFET) HEMT implementations with reduced area consumption and higher performance, as compared to conventional implementations. For example, certain aspects are directed to a HEMT device with increased drive current and output power capabilities, and increased current gain cut-off frequency (Ft)/maximum oscillation frequency (Fmax) performance. Some of these HEMTs may be implemented with gallium nitride (GaN) and/or as complementary metal-oxide-semiconductor (CMOS) logic.

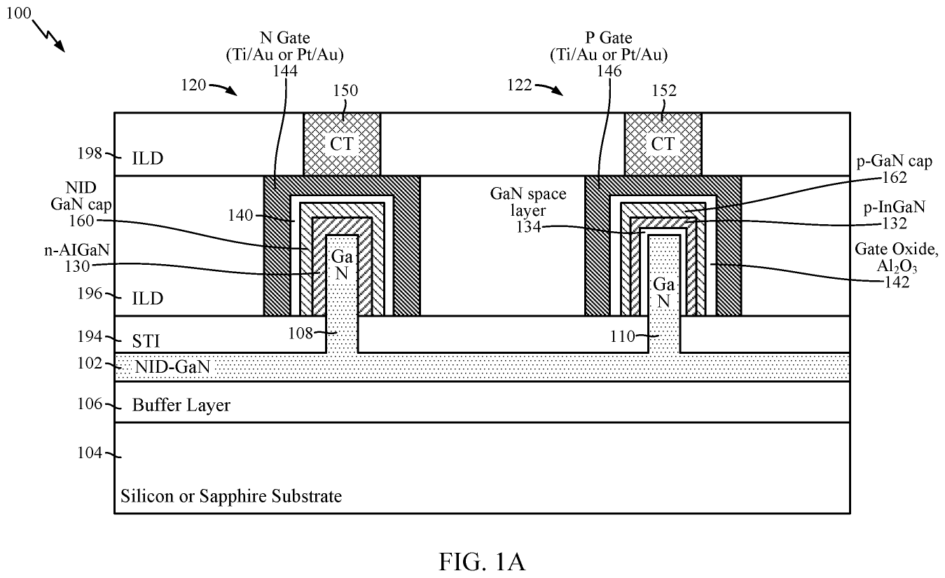

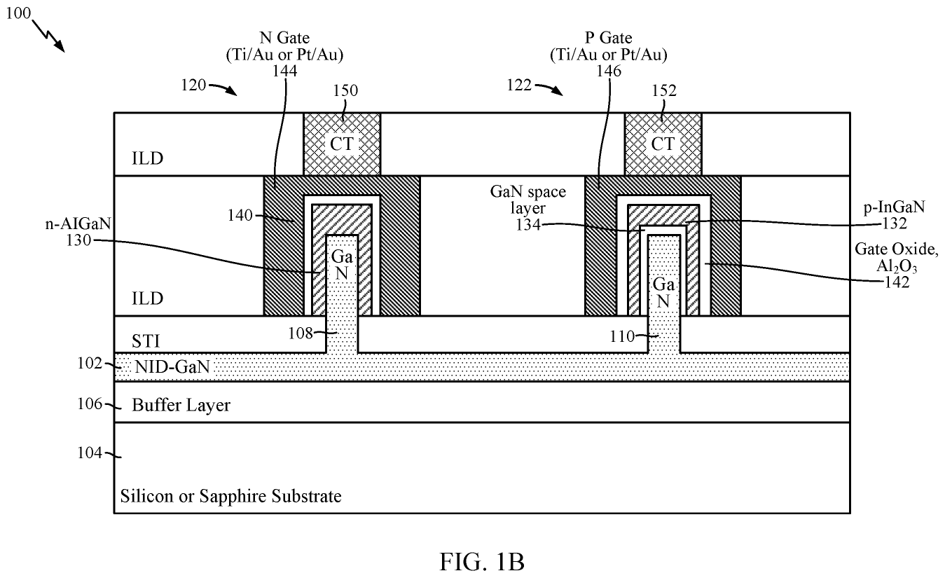

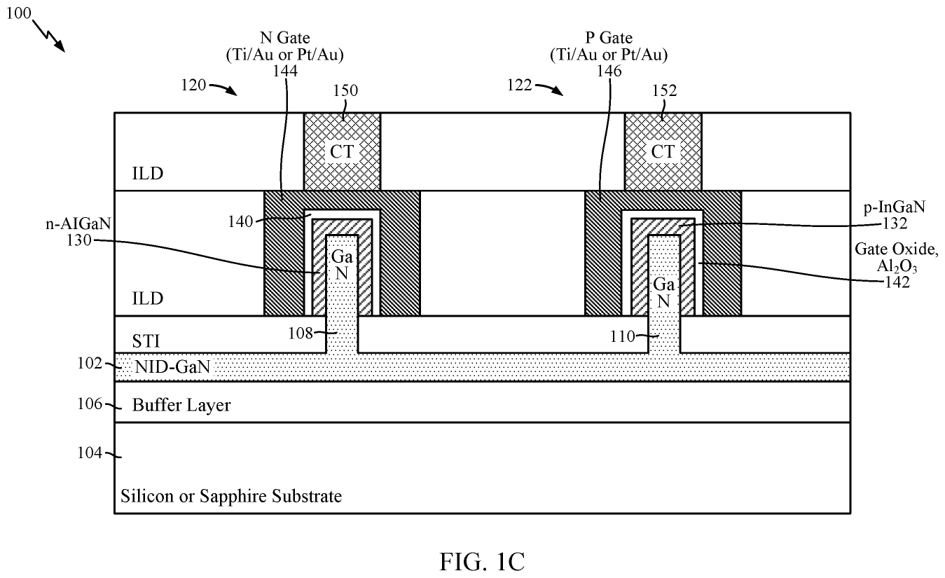

FIGS. 1A, 1B, and 1C illustrate example implementations of a 3D finFET triple gate HEMT device 100, in accordance with certain aspects of the present disclosure. The HEMT device 100 is referred to as a triple gate HEMT device as each gate region is adjacent to three sides (e.g., top and two lateral sides) of a respective fin, as illustrated. The HEMT device 100 may be implemented as a CMOS device having a finFET n-type GaN HEMT 120, and a finFET p-type GaN HEMT 122. Although GaN is utilized in the HEMT device 100, it is to be understood that any Group III/V combination of chemical elements may be used. For ease of description, the remainder of the present disclosure describes GaN. For example, the HEMT device 100 may include a channel region 102, which may be formed above a substrate 104 (e.g., silicon or sapphire substrate) and a buffer layer 106 (e.g., a support layer). As illustrated, the channel region 102 may be implemented using non-intentionally doped (NID) GaN, having fins 108, 110. In certain aspects, a barrier layer 130, 132 (e.g., n-type aluminum gallium nitride (AlGaN) or p-type indium gallium nitride (InGaN), respectively) may be implemented adjacent to each of the fins 108, 110. Each of the barrier layers 130, 132 forms a heterojunction with a respective channel implemented using fins 108, 110. For the p-type HEMT 122, a spacer layer 134 (e.g., GaN spacer layer) may be implemented between the barrier layer 132 and the fin 110, as illustrated.

In certain aspects, the n-type HEMT 120 and p-type HEMT 122 may include a cap region 160 (e.g., NID GaN cap region) and/or a cap region 162 (e.g. p-type GaN cap region). As illustrated, a gate oxide layer 140, 142, which may be implemented using any of various suitable materials, such as aluminum oxide (Al₂O₃), may be disposed adjacent to each of the cap regions 160, 162. An n-type gate region 144 and a p-type gate region 146 may be disposed adjacent to the gate oxide layers 140, 142, as illustrated. The n-type gate region 144 and the p-type gate region 146 may be metal gate regions implemented using titanium gold (Ti/Au) or platinum gold (Pt/Au), for example, each of which may be coupled to a contact 150, 152 (CT) for electrical contact. In certain aspects, the n-type HEMT 120 and p-type HEMT 122 may be implemented without the cap regions 160, 162, as illustrated in FIG. 1B. In certain aspects, the p-type HEMT 122 may be implemented without the spacer layer 134, as illustrated in FIG. 1C. In certain aspects, the HEMT device 100 also includes shallow trench isolation (STI) region 194, as well as interlayer dielectric (ILD) regions 196, 198, as illustrated.

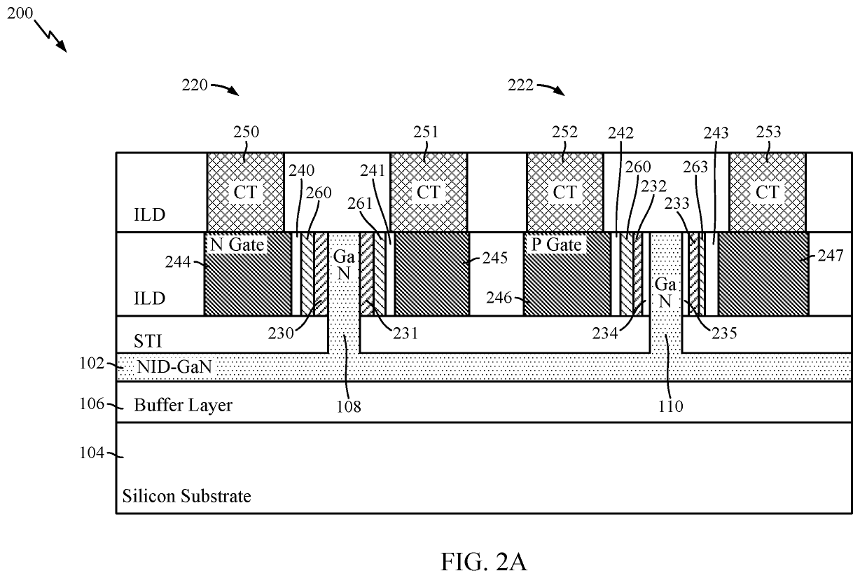

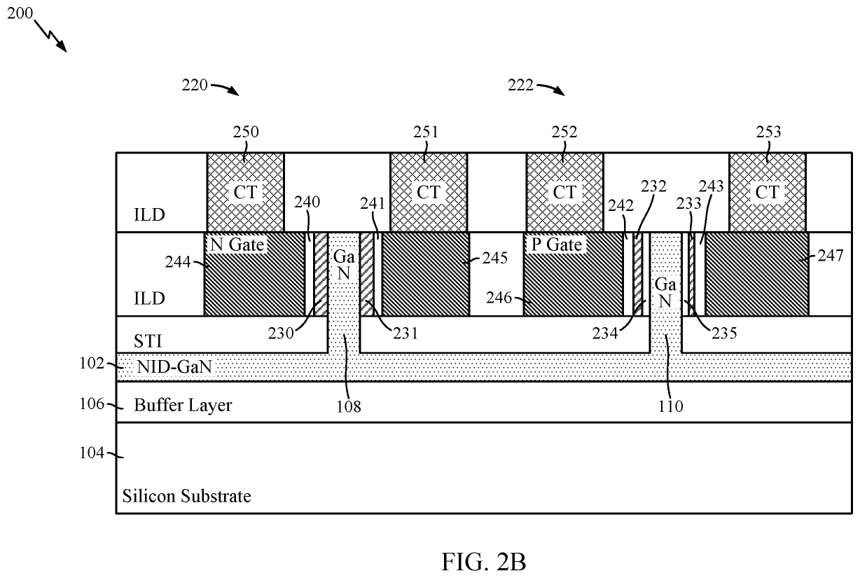

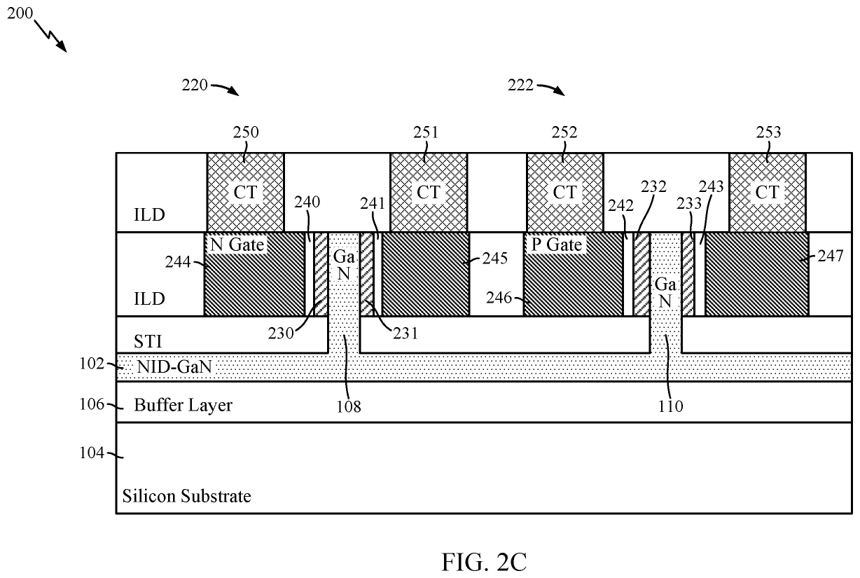

FIGS. 2A, 2B, and 2C illustrate example implementations of a 3D finFET double gate HEMT device 200, in accordance with certain aspects of the present disclosure. The HEMT device 200 is referred to as a double gate HEMT device as each gate region is adjacent to two sides (e.g., two lateral sides) of a respective fin, as illustrated. The HEMT device 200 may be implemented as a CMOS device having a finFET n-type GaN HEMT 220, and a finFET p-type GaN HEMT 222. Although GaN is utilized in the HEMT device 200, it is to be understood that any Group III/V combination of chemical elements may be used. As illustrated in this example, the n-type HEMT 220 may include a channel region 102, which may be formed above a substrate 104 (e.g., a silicon or sapphire substrate) and a buffer layer 106 (e.g., a support layer). In certain aspects, barrier layers 230, 231, 232, 233 (e.g., n-type aluminum gallium nitride (AlGaN) or p-type indium gallium nitride (InGaN), respectively) may be implemented adjacent to each of the respective fins 108, 110. For the p-type HEMT 122, spacer layers 234, 235 (e.g., GaN spacer layers) may be implemented between a respective one of barrier layers 232, 233 and the fin 110, as illustrated.

In certain aspects, the n-type HEMT 220 and p-type HEMT 222 may include cap regions 260, 261, 262, 263 (e.g., NID GaN cap regions or p-type GaN cap region). As illustrated, gate oxide layers 240, 241, 242, 243, which may be implemented using any of various suitable materials (e.g., Al₂O₃), may be disposed adjacent to each of respective cap regions 260, 261, 262, 263. N-type gate regions 244, 245 and p-type gate regions 246, 247 may be disposed adjacent to a respective one of the gate oxide layers 240, 241, 242, 243, as illustrated. The n-type gate regions 244, 245 and the p-type gate regions 246, 247 may be implemented using Ti/Au or Pt/Au, each of which may be coupled to a respective CT 250, 251, 252, 253. In certain aspects, the n-type HEMT 220 and p-type HEMT 222 may be implemented without the cap regions 260, 261, 262, 263, as illustrated in FIG. 2B. In certain aspects, the p-type HEMT 222 may be implemented without the spacer layers 234, 235, as illustrated in FIG. 2C.

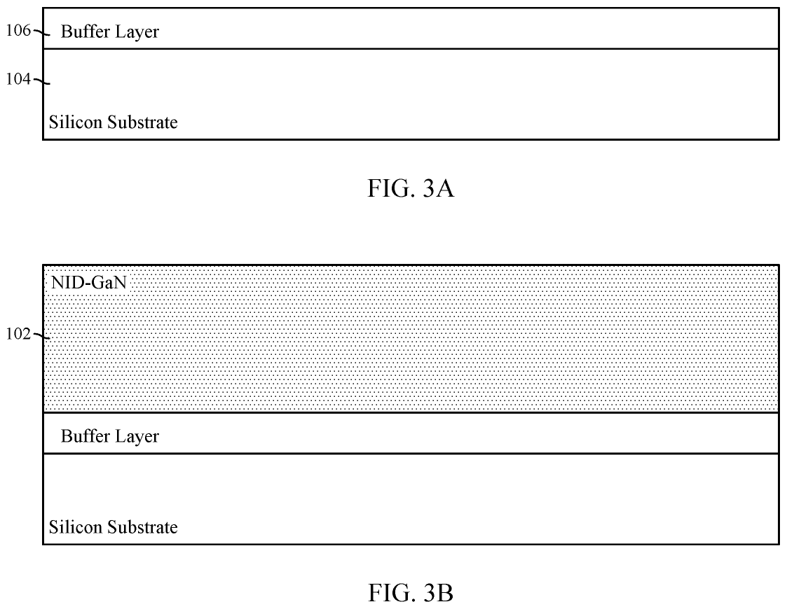

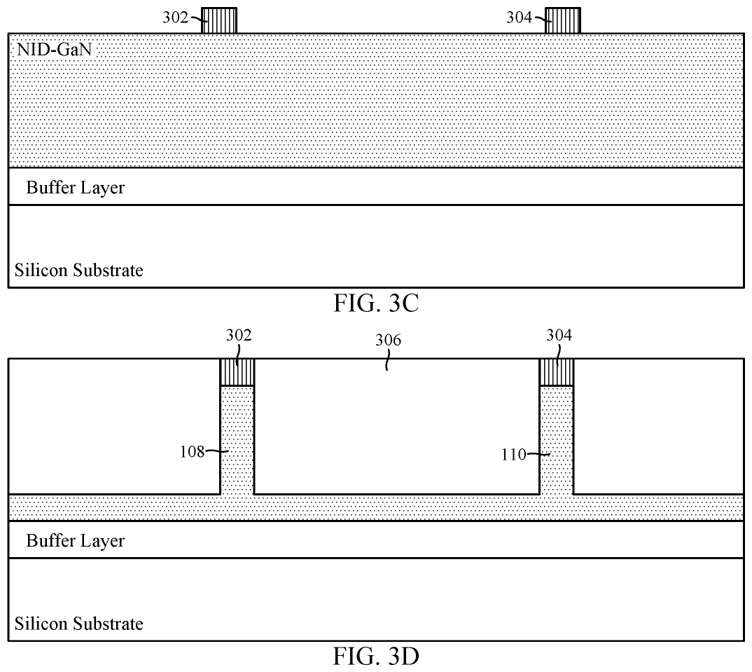

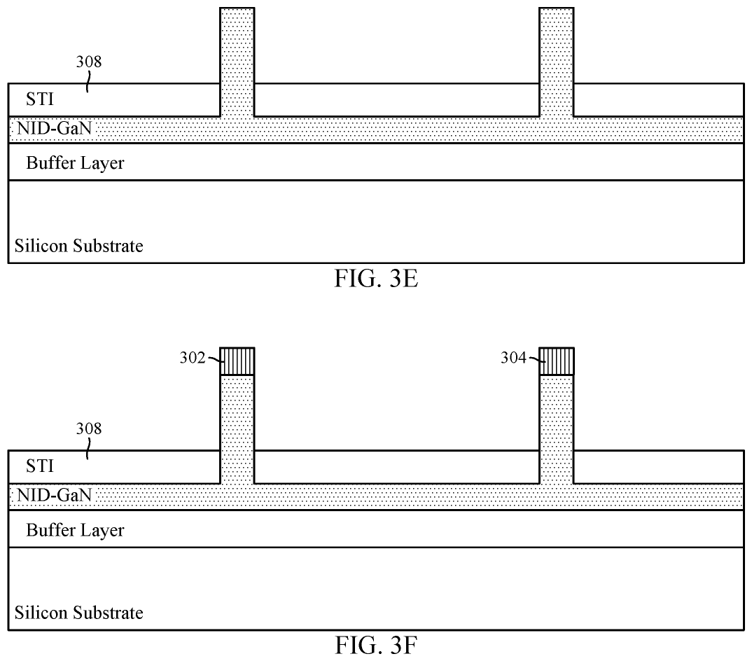

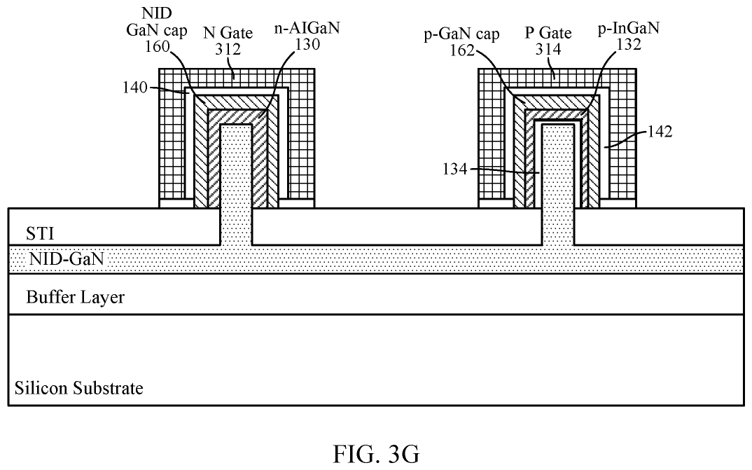

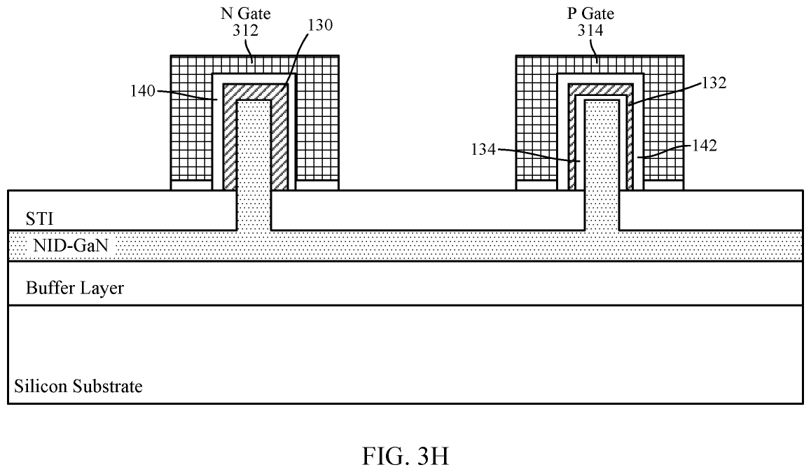

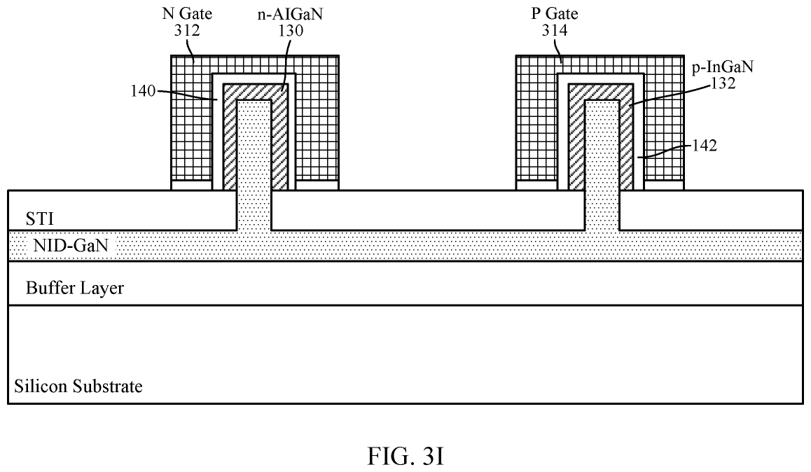

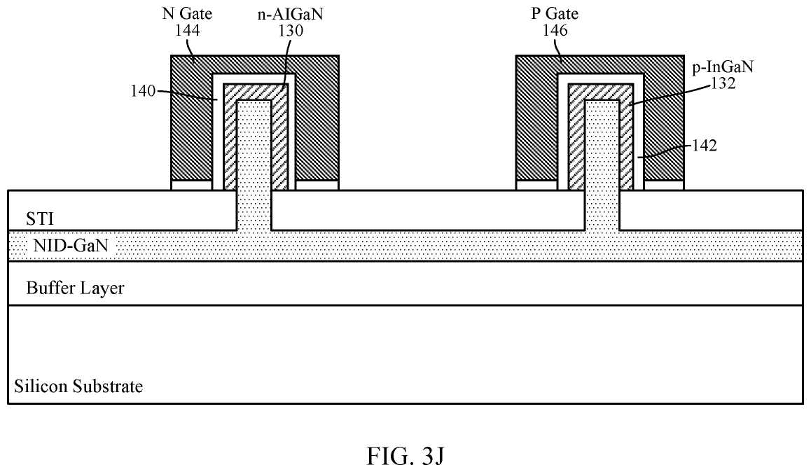

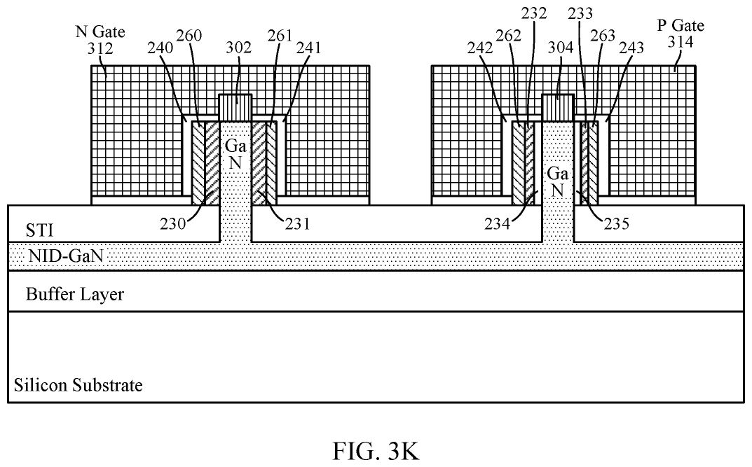

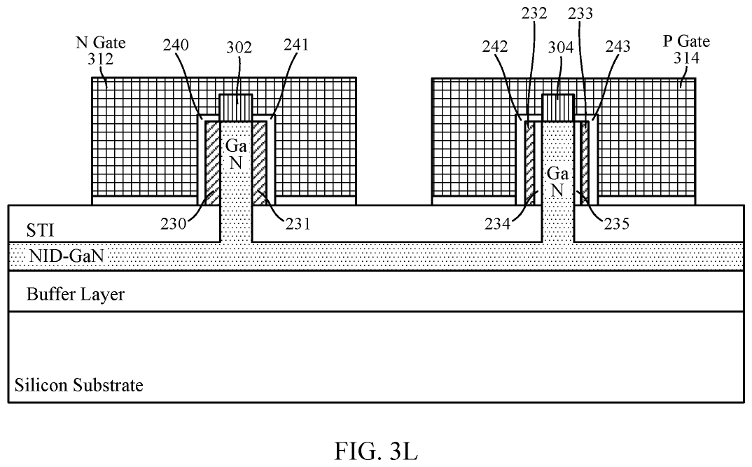

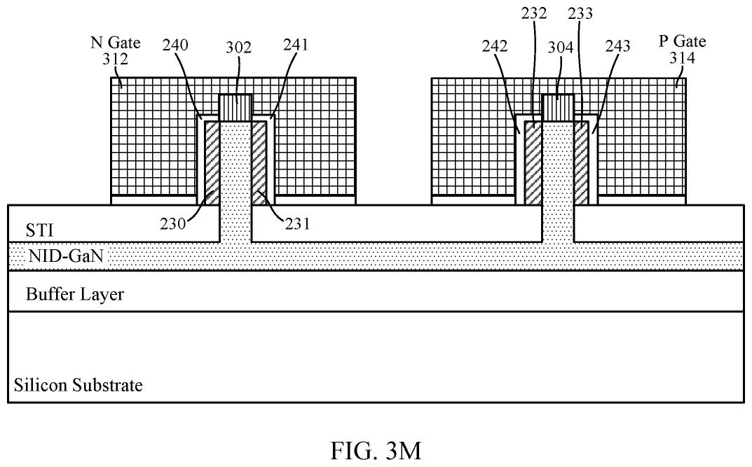

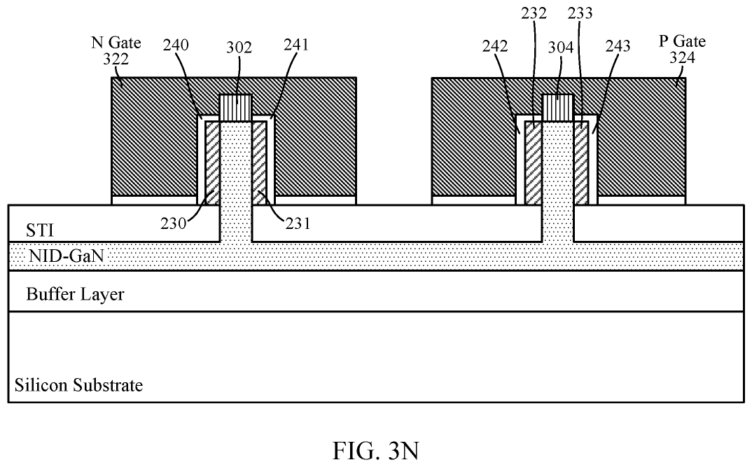

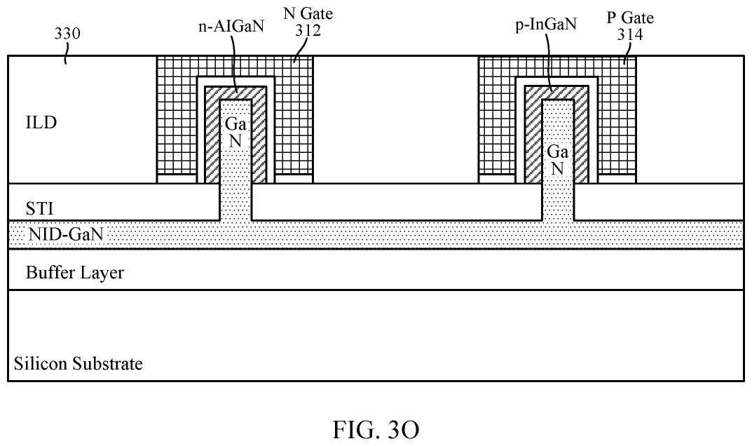

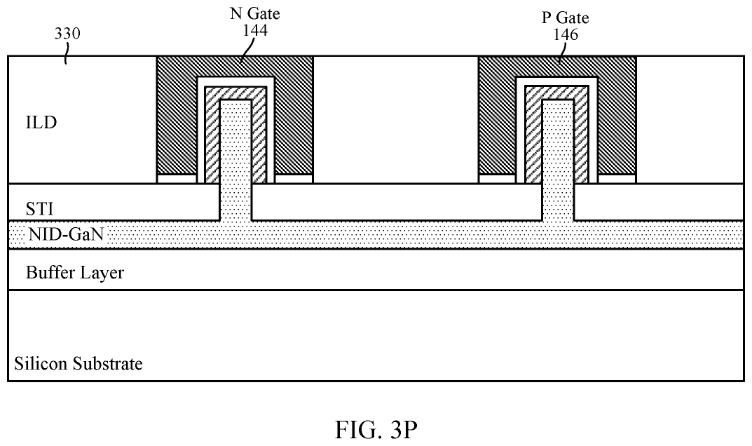

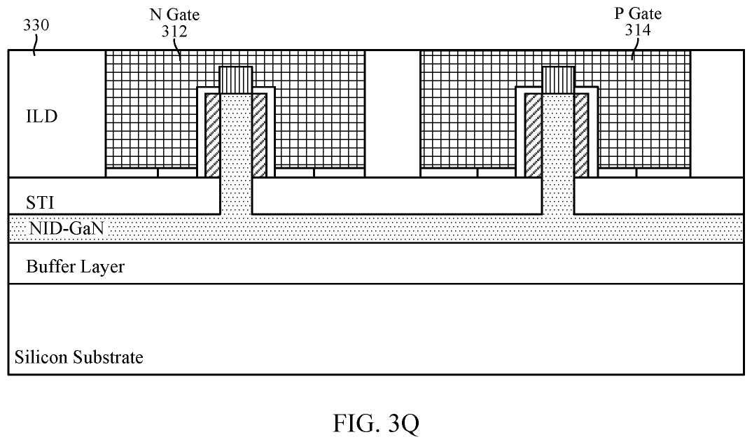

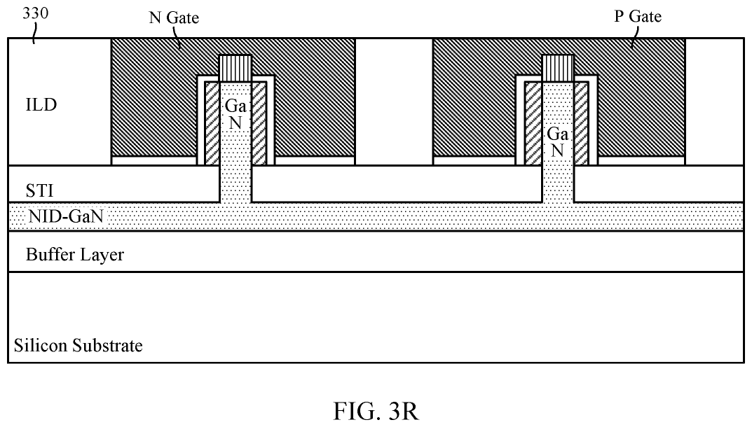

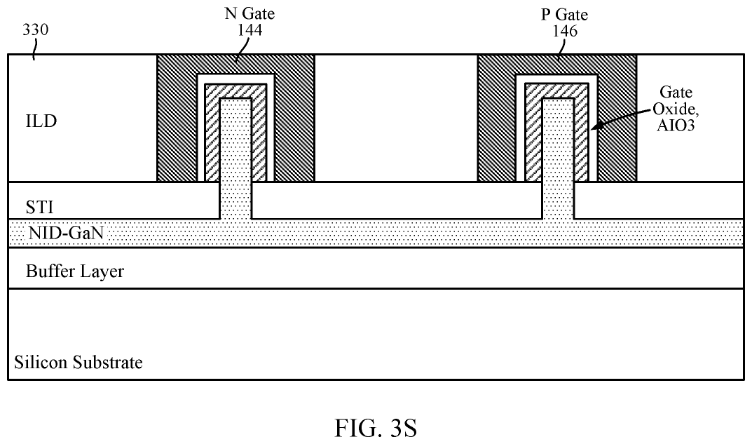

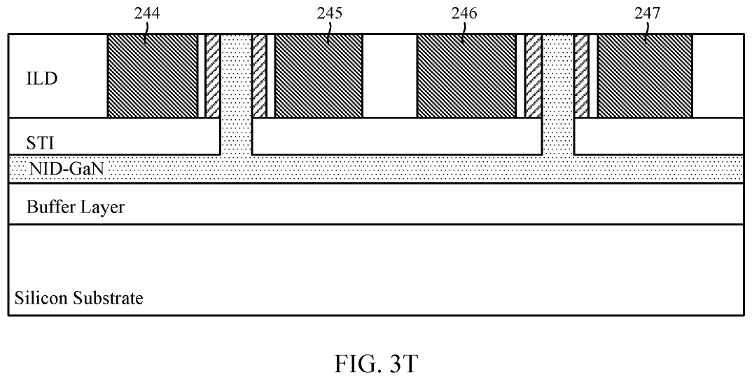

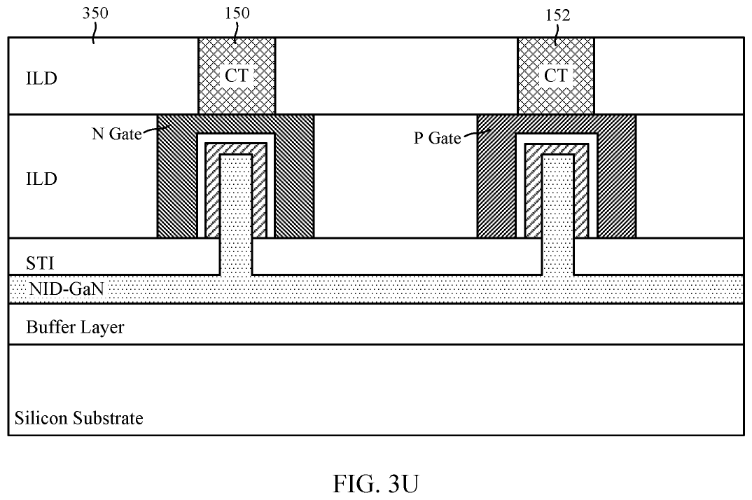

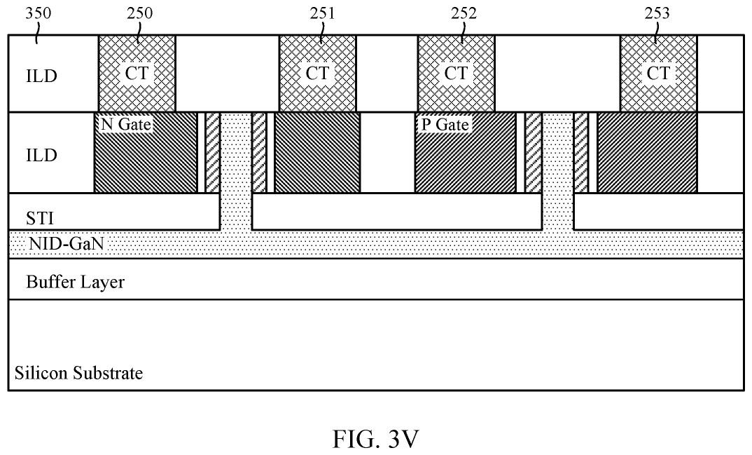

FIGS. 3A-3V illustrate example operations for fabricating a semiconductor device, in accordance with certain aspects of the present disclosure. As illustrated in FIG. 3A, a buffer layer 106 may be (epitaxially) grown from a substrate 104 (e.g., a silicon substrate). The buffer layer 106 may be implemented using at least one of aluminum nitride (AlN), AlGaN, or GaN. As illustrated in FIG. 3B, the channel region 102 (e.g., GaN layer) may be grown. In certain aspects, the channel region may be implemented using NID GaN, or a high resistive (HR) material. In certain aspects, silicon nitride (Si₃N₄) hard mask (HM) layers 302, 304 may be deposited and patterned for fin formation, as illustrated in FIG. 3C. The fins 108, 110 may be etched, followed by depositing of silicon dioxide 306 (SiO₂) and chemical-mechanical polishing (CMP) stopped at the top of the HM layers 302, 304, as illustrated in FIG. 3D.

The HM layers 302, 304 may then be removed, followed by an oxide dip to form a shallow trench isolation (STI) region 308, as illustrated in FIG. 3E. In certain aspects, the HM layers 302, 304 may not be removed prior to the oxide dip, as illustrated in FIG. 3F.

After the removal of the HM layers 302, 304 per FIG. 3E and the formation of the STI region 308, the cap regions 160, 162 and barrier layers 130, 132 may be formed using epitaxial growth from fin sidewalls and fin top, separately. Gate oxide layers 140, 142 (e.g., implemented using aluminum oxide (Al₂O₃)) may then be deposited, followed by deposition of dummy gates 312, 314 (e.g., poly) with gate patterning, as illustrated in FIG. 3G. In certain aspects, the cap regions 160, 162 may not be formed, as illustrated in FIG. 3H, in order to fabricate the HEMT device 100 described with respect to FIG. 1B, for example.

In certain aspects, when fabricating the HEMT device 100 described with respect to FIG. 1C, the spacer layer 134 may not be formed, as illustrated in FIG. 3I. In certain aspects, instead of forming dummy gates 312, 314, gate regions 144, 146 may be deposited, and the metal gates may be patterned by a lifting or etch process, as illustrated in FIG. 3J.

In certain aspects, the cap regions 260, 262 and barrier layers 230, 232 may be formed using epitaxial growth from fin sidewalls without the prior removal of the HM layers 302, 304, as illustrated in FIG. 3K, in order to fabricate the HEMT device 200 described with respect to FIG. 2A, for example. Gate oxide layers 240, 241, 242, 243 may then be deposited, followed by deposition of dummy gates 312, 314 with gate patterning. In certain aspects, when fabricating the HEMT device 200 described with respect to FIG. 2B, the cap regions 260, 261, 262, 263 may not be formed, as illustrated in FIG. 3L. In certain aspects, when fabricating the HEMT device 200 described with respect to FIG. 2C, the spacer layers 234, 235 may not be formed, as illustrated in FIG. 3M. In some cases, instead of forming dummy gates 312, 314, metal gates 322, 324 may be deposited, and the metal gates may be patterned by a lifting or etch process, as illustrated in FIG. 3N.

In certain aspects, after the dummy gate formation as described with respect to FIG. 3I, oxide 330 may be deposited, followed by CMP, as illustrated in FIG. 3O. As illustrated in FIG. 3P, the oxide 330 may be deposited after the formation of gate regions 144, 146 as described with respect to FIG. 3J. In certain aspects, after the formation of the dummy gates 312, 314 as described with respect to FIG. 3M, oxide 330 may be deposited as illustrated in FIG. 3Q. In certain aspects, after the formation of the metal gates 322, 324 as described with respect to FIG. 3N, oxide 330 may be deposited as illustrated in FIG. 3R.

In certain aspects, after the oxide 330 is deposited as described with respect to FIG. 3O, the dummy gates 312, 314 are removed and filled with metal to form gate regions 144, 146, as illustrated in FIG. 3S. In certain aspects, after the oxide 330 is deposited as described with respect to FIG. 3Q, the dummy gates 312, 314 are removed and filled with metal to form the gate regions 244, 245, 246, 247, as illustrated in FIG. 3T.

As illustrated in FIG. 3U, after formation of the gate regions 144, 146 as described with respect to FIG. 3S, oxide 350 is formed, followed by opening and filling of trenches to form CTs 150, 152, and CMP of the CTs 150, 152 and oxide 350. As illustrated in FIG. 3V, after formation of the gate regions 244, 245, 246, 247 as described with respect to FIG. 3T, oxide 350 is formed, followed by opening and filling of trenches to form CTs 250, 251, 252, 253 and CMP of the oxide 250 and the CTs 250, 251, 252, 253.

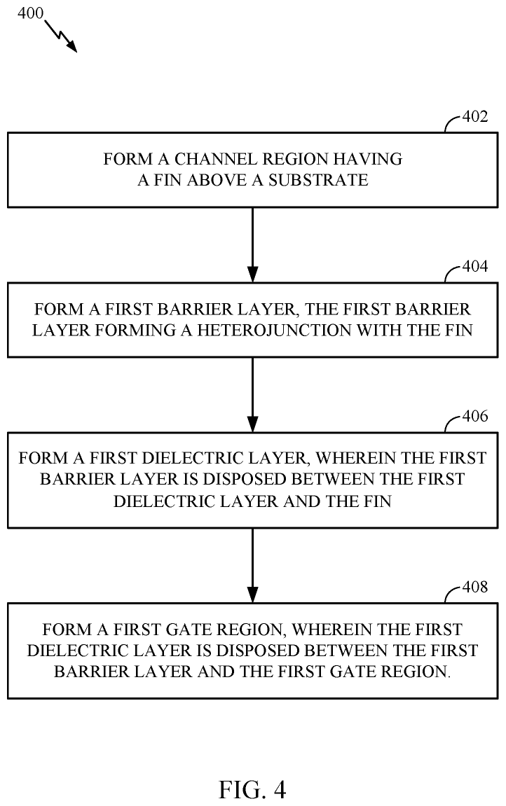

FIG. 4 is a flow diagram illustrating example operations 400 for fabricating a semiconductor device, in accordance with certain aspects of the present disclosure. The operations 400 may be performed by a semiconductor processing chamber.

The operations 400 begin, at block 402, with the chamber forming a channel region (e.g., channel region 102) having a fin (e.g., fin 108) above a substrate (e.g., substrate 104). At block 404, the chamber forms a first barrier layer (e.g., barrier layer 130 or barrier layer 230), the first barrier layer forming a heterojunction with the fin, and at block 406, the chamber forms a first dielectric layer (e.g., oxide layer 140 or oxide layer 240). In certain aspects, the first barrier layer may be disposed between the first dielectric layer and the fin. In certain aspects, at block 408, a first gate region (e.g., gate region 144 or gate region 244) is formed by the chamber. For example, the first dielectric layer may be disposed between the first barrier layer and the first gate region. In certain aspects, a spacer layer (e.g., spacer layer 134 or spacer layer 234) may be formed by the chamber and may be disposed between the fin and the first barrier layer.

In certain aspects, the operations 400 also include the chamber forming a second barrier layer (e.g., barrier layer 231) and forming a second dielectric layer (e.g., oxide layer 241). The second barrier layer may be disposed between the second dielectric layer and the fin. The operations 400 may also include the chamber forming a second gate region (e.g., gate region 245). The second dielectric layer may be disposed between the second barrier layer and the second gate region. In certain aspects, the operations 400 may also include the chamber forming a first cap region (e.g., cap region 260), the first cap region may be disposed between the first barrier layer and the first dielectric layer. The chamber may also form a second cap region (e.g., cap region 261). The second cap region may be disposed between the second barrier layer and the second dielectric layer.

In certain aspects, the first gate region may be formed by the chamber adjacent to a first lateral side, a second lateral side, and a top side of the first dielectric layer. In certain aspects, the first dielectric layer may be formed by the chamber adjacent to a first lateral side, a second lateral side, and a top side of the first barrier layer. In certain aspects, the first barrier layer may be formed by the chamber adjacent to a first lateral side, a second lateral side, and a top side of the fin. In certain aspects, the operations 400 also include the chamber forming a cap region (e.g., cap region 160) adjacent to the first lateral side, the second lateral side, and the top side of the first barrier layer such that the cap region is disposed between the first barrier layer and the first dielectric layer.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage, or mode of operation. The term “coupled” is used herein to refer to the direct or indirect coupling between two objects. For example, if object A physically touches object B and object B touches object C, then objects A and C may still be considered coupled to one another—even if objects A and C do not directly physically touch each other. For instance, a first object may be coupled to a second object even though the first object is never directly physically in contact with the second object. The terms “circuit” and “circuitry” are used broadly and intended to include both hardware implementations of electrical devices and conductors that, when connected and configured, enable the performance of the functions described in the present disclosure, without limitation as to the type of electronic circuits.

The apparatus and methods described in the detailed description are illustrated in the accompanying drawings by various blocks, modules, components, circuits, steps, processes, algorithms, etc. (collectively referred to as “elements”). These elements may be implemented using hardware, for example.

One or more of the components, steps, features, and/or functions illustrated herein may be rearranged and/or combined into a single component, step, feature, or function or embodied in several components, steps, or functions. Additional elements, components, steps, and/or functions may also be added without departing from features disclosed herein. The apparatus, devices, and/or components illustrated herein may be configured to perform one or more of the methods, features, or steps described herein.

It is to be understood that the specific order or hierarchy of steps in the methods disclosed is an illustration of exemplary processes. Based upon design preferences, it is understood that the specific order or hierarchy of steps in the methods may be rearranged. The accompanying method claims present elements of the various steps in a sample order, and are not meant to be limited to the specific order or hierarchy presented unless specifically recited therein.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but are to be accorded the full scope consistent with the language of the claims, wherein reference to an element in the singular is not intended to mean “one and only one” unless specifically so stated, but rather “one or more.” Unless specifically stated otherwise, the term “some” refers to one or more. A phrase referring to “at least one of” a list of items refers to any combination of those items, including single members. As an example, “at least one of: a, b, or c” is intended to cover at least: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c). All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112(f) unless the element is expressly recited using the phrase “means for” or, in the case of a method claim, the element is recited using the phrase “step for.”

What is claimed is:

1. A semiconductor device comprising:
a substrate;
a channel region having a first fin disposed above the substrate;
a first barrier layer disposed adjacent to a first side and a second side of the first fin, wherein the first side and the second side of the first fin are opposite sides, the first barrier layer forming a heterojunction with the fin;
a first dielectric layer disposed adjacent to a first side and a second side of the first barrier layer, wherein the first side and the second side of the first barrier layer are opposite sides; and
a first gate region disposed adjacent to the first dielectric layer.

2. The semiconductor device of claim 1, further comprising a cap region interposed between the first dielectric layer and the first side and the second side of the first barrier layer.

3. The semiconductor device of claim 1, further comprising a spacer layer interposed between the first barrier layer and the first side and the second side of the first fin.

4. The semiconductor device of claim 1, wherein:
the first gate region is disposed adjacent to a first lateral side, a second lateral side, and a top side of the first dielectric layer;
the first side and the second side of the first fin comprise a first lateral side and a second lateral side of the first fin, the first barrier layer being further adjacent to a top side of the first fin; and
the first side and the second side of the first barrier layer comprise a first lateral side and a second lateral side of the first barrier layer, the first dielectric layer being further adjacent to a top side of the first barrier layer.

5. The semiconductor device of claim 1, wherein the channel region comprises gallium nitride (GaN) and wherein the first barrier layer comprises aluminum gallium nitride (AlGaN).

6. The semiconductor device of claim 1, wherein the channel region comprises a second fin, the semiconductor device further comprising:
a second barrier layer disposed adjacent to a first side and a second side of the second fin, the first side and the second side of the second fin being opposite sides;
a second dielectric layer disposed adjacent to a first side and a second side of the second barrier layer, the first side and the second side of the second barrier layer being opposite sides; and
a second gate region disposed adjacent to the second dielectric layer, wherein:
the first barrier layer and the first gate region are doped n-type; and
the second barrier layer and the second gate region are doped p-type.

7. The semiconductor device of claim 1, wherein the semiconductor device comprises a high electron mobility transistor.

8. The semiconductor device of claim 1, further comprising a buffer layer disposed between the substrate and the channel region.

9. A semiconductor device comprising:
a substrate;
a channel region having a fin disposed above the substrate;
a first barrier layer;
a second barrier layer;
a first dielectric layer, wherein the first barrier layer is disposed between the first dielectric layer and the fin, the first barrier layer forming a first heterojunction with the fin;
a second dielectric layer, wherein the second barrier layer is disposed between the second dielectric layer and the fin, the second barrier layer forming a second heterojunction with the fin;
a first gate region, wherein the first dielectric layer is disposed between the first barrier layer and the first gate region; and
a second gate region, wherein the second dielectric layer is disposed between the second barrier layer and the second gate region.

10. The semiconductor device of claim 9, wherein the first gate region and the second gate region comprise metal gate regions.

11. The semiconductor device of claim 9, further comprising:
a first cap region disposed between the first barrier layer and the first dielectric layer; and
a second cap region disposed between the second barrier layer and the second dielectric layer.

12. The semiconductor device of claim 9, further comprising:
a first spacer layer disposed between the fin and the first dielectric layer; and
a second spacer layer disposed between the fin and the second dielectric layer.

13. The semiconductor device of claim 9, wherein the channel region comprises gallium nitride (GaN) and wherein the first barrier layer comprises aluminum gallium nitride (AlGaN).

14. The semiconductor device of claim 9, wherein the first gate region and the second gate region are electrically isolated.

15. A method for fabricating a semiconductor device, comprising:
forming a channel region having a fin above a substrate;
forming a first barrier layer, the first barrier layer forming a heterojunction with the fin;
forming a first dielectric layer, wherein the first barrier layer is disposed between the first dielectric layer and the fin; and
forming a first gate region, wherein the first dielectric layer is disposed between the first barrier layer and the first gate region.

16. The method of claim 15, further comprising forming a spacer layer, wherein the spacer layer is disposed between the fin and the first barrier layer.

17. The method of claim 15, further comprising:
forming a second barrier layer;
forming a second dielectric layer, wherein the second barrier layer is disposed between the second dielectric layer and the fin; and
forming a second gate region, wherein the second dielectric layer is disposed between the second barrier layer and the second gate region.

18. The method of claim 17, further comprising:
forming a first cap region, wherein the first cap region is disposed between the first barrier layer and the first dielectric layer; and
forming a second cap region, wherein the second cap region is disposed between the second barrier layer and the second dielectric layer.

19. The method of claim 15, wherein:
the first gate region is formed adjacent to a first lateral side, a second lateral side, and a top side of the first dielectric layer;
the first dielectric layer is formed adjacent to a first lateral side, a second lateral side, and a top side of the first barrier layer; and
the first barrier layer is formed adjacent to a first lateral side, a second lateral side, and a top side of the fin.

20. The method of claim 19, further comprising forming a cap region adjacent to the first lateral side, the second lateral side, and the top side of the first barrier layer such that the cap region is disposed between the first barrier layer and the first dielectric layer.
